(19) United States
(12) Patent Application Publication
(10) Pub. No.: US 2020/0064737 A1
(43) Pub. Date: Feb. 27, 2020

(54) SUBSTRATE PROCESSING APPARATUS AND METHOD

(71) Applicant: ASM IP Holding B.V., Almere (NL)

(72) Inventor: David Kurt de Roest, Kessel-Lo (BE)

(21) Appl. No.: 16/546,543

(22) Filed: Aug. 21, 2019

Related U.S. Application Data
(60) Provisional application No. 62/722,045, filed on Aug. 23, 2018.

(51) Int. Cl. G03F 7/16; H01L 21/027; H01L 21/67

(52) U.S. Cl. CPC G03F 7/16; H01L 21/67225; H01L 21/0274

(57) ABSTRACT

A substrate processing apparatus comprising a wet processing station with a resist coating device for coating a resist on a substrate and/or a development processing device for developing the resist on the substrate is disclosed. The apparatus may have an additional processing station and a substrate handler for moving the substrate to the wet, and/or additional processing station and moving the substrate in a direction in and/or out of the substrate processing apparatus. The additional processing station comprises an infiltration device.

### CROSS-REFERENCE TO RELATED APPLICATION

This application claims the benefit of U.S. Provisional Application No. 62/722,045, entitled “SUBSTRATE PROCESSING APPARATUS AND METHOD” filed on Aug. 23, 2018, which is hereby incorporated by reference in its entirety for all purposes.

### FIELD OF INVENTION

The present disclosure relates generally to a substrate processing apparatus and a method of using it. The apparatus comprises:

a wet processing station comprising a resist coating device for coating a resist on a substrate and/or a development processing device for developing the resist on the substrate:

an additional processing station; and,

a substrate handler for moving the substrate to the wet, and/or additional processing station and moving the substrate in a direction in and/or out of the substrate processing apparatus.

### BACKGROUND OF THE DISCLOSURE

The substrate processing apparatus may be referred to as coater/developer apparatus or track for example. The substrate processing apparatus may be used to perform different process steps on the substrate before and after pattern formation in a resist layer on the substrate. For example, if contaminations are present on the substrate they may be removed by a chemical treatment. The substrate may be heated to a temperature sufficient to drive off any moisture that may be present on the substrate. An adhesion promoter may be applied to promote adhesion of the resist on the substrate in the substrate processing apparatus.

In a wet processing station of the substrate processing apparatus the substrate may be covered with resist by spin coating. A viscous, liquid solution of resist may be dispensed onto the substrate, and the substrate may be spun to produce a thin uniform layer. The resist-coated wafer may then be baked to evaporate resist solvent.

If the resist is a photo(sensitive)resist the substrate may than be transferred from the substrate processing apparatus to a lithographic exposure apparatus. In the lithographic exposure apparatus, the substrate with photoresist may be exposed to a patterned radiation beam of (extreme) ultraviolet radiation. The exposure to radiation causes a chemical change in the photoresist patterning the resist.

The substrate with the patterned resist may be transferred back to the wet processing station of the substrate processing apparatus in which some of the resist may be removed by a special developer solution. Positive photoresist becomes soluble in the developer after exposure while for negative photoresist unexposed regions become soluble in the developer. The developer may be delivered in the wet processing station on a spinner, much like the resist. A post-exposure bake may be used before developing and/or a bake may be used after developing.

As semiconductor device structures trend towards smaller and smaller geometries, different patterning techniques have arisen. These techniques include self-aligned multiple patterning, spacer defined quadruple patterning, deep ultraviolet lithography (DUV), extreme ultraviolet lithography, and DUV/EUV combined with spacer defined double patterning.

The patterning techniques described above may utilize a resist disposed on the substrate to enable high resolution patterning of the substrate. To satisfy the requirements of both high resolution and low line-edge roughness, the resist may be a thin layer. However, such thin resists may have several drawbacks. For example, high resolution resists may suffer from one or more of a high defectivity, a high roughness and a high etch rate. The high etch rate may be caused by a low etch resistance of the resist and makes the transfer of the patterned resist to the underlying layers more difficult. The defectivity, roughness and etch resistance may even deteriorate when the advanced high resolution resists need to be further downscaled.

An improved substrate processing apparatus for providing infiltrateable material such as resist or hard masks with improved properties may therefore be desirable.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments a substrate processing apparatus is disclosed. The processing apparatus may comprise a wet processing station comprising a resist coating device for coating a resist on a substrate and/or a development processing device for developing the resist on the substrate. The processing apparatus may comprise an additional processing station and a substrate handler for moving the substrate to the wet, and/or additional processing station and moving the substrate in a direction in and/or out of the substrate processing apparatus. The additional processing station may comprise an infiltration device comprising a reaction chamber provided with a substrate holder to hold at least one substrate with infiltrateable material; a precursor distribution and removal system comprising one or more reaction chamber valves to provide to/and remove from the reaction chamber a gaseous first precursor; and, a sequence controller operably connected to the precursor distribution and removal system and comprising a memory provided with a program to execute infiltration of the infiltrateable material on the substrate when run on the sequence controller by an infiltration cycle. The infiltration cycle may comprise activating the precursor distribution and removal system to provide the first precursor for a first period in the reaction chamber. The infiltrateable material may be infiltrated with the reaction products of the reaction of the infiltrateable material with the first precursor.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a substrate processing apparatus according to embodiment of the disclosure.

FIG. 2 illustrates a non-limiting exemplary additional processing station for the substrate processing apparatus of FIG. 1.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “substrate” may refer to any underlying material or materials that may be used, or upon which, a device, a circuit, or a film may be formed. Additionally, the term “infiltrateable material” may refer to any material into which an additional species, such as atoms, molecules, or ions, may be introduced. The term “semiconductor device structure” may refer to any portion of a processed, or partially processed, semiconductor structure that is, includes, or defines at least a portion of an active or passive component of a semiconductor device to be formed on or in a semiconductor substrate. For example, semiconductor device structures may include, active and passive components of integrated circuits, such as, for example, transistors, memory elements, transducers, capacitors, resistors, conductive lines, conductive vias, and conductive contact pads.

A number of example materials are given throughout the embodiments of the current disclosure, it should be noted that the chemical formulas given for each of the example materials should not be construed as limiting and that the non-limiting example materials given should not be limited by a given example stoichiometry.

The present disclosure includes a substrate processing apparatus and processing methods that may be utilized to improve the properties of infiltrateable materials, such as, for example, resists and hardmask materials, employed as etch masks in semiconductor device fabrication processes.

Infiltration processes, such as, for example, sequential infiltration synthesis (SIS), have been demonstrated to increase the etch resistance of various organic materials by modifying the material with an inorganic protective component. For example, the SIS process utilizes alternating exposures of the polymer resist to gas phase precursors that infiltrate the organic resist material to form a protective component within the resist layer. The SIS process and its uses are described in U.S. Publication No. 2012/0241411, and/or U.S. Publication No. 2018/0171475 and incorporated by reference herein. Therefore, combining infiltration processes with high resolution resists and hardmask patterning in a substrate processing apparatus may provide benefits previously unseen with prior approaches, such as the one described in U.S. Publication No. 2014/0273514 and/or U.S. Pat. No. 9,916,980 B1, and incorporated by reference herein.

Infiltration processes may be accomplished with dedicated infiltration tools which may comprise a reaction chamber constructed and arranged to hold at least a substrate provided with an infiltrateable material thereon. Such reaction chambers may include reaction chambers configured for atomic layer deposition (ALD) processes, as well as reaction chambers configured for chemical vapor deposition (CVD) processes. A showerhead reaction chamber may be used. A cross-flow, batch, minibatch, or spatial ALD reaction chambers may be used. A batch reaction chamber such as a vertical batch reaction chamber may be used. In other embodiments, a batch reaction chamber comprises a minibatch reactor configured to accommodate 10 or fewer wafers, 8 or fewer wafers, 6 or fewer wafers, 4 or fewer wafers, or 2 or fewer wafers. A stand-alone infiltration tool may be utilized including a reaction chamber that may be constructed and arranged to solely perform infiltration processes. The resist may be very sensitive and therefore infiltration may be applied very quickly after the resist is patterned.

Therefore, in some embodiments of the disclosure a substrate processing apparatus may be provided with infiltration capabilities. In some embodiments the substrate processing apparatus may comprise a wet processing station comprising a resist coating device for coating a resist on a substrate and/or a development processing device for developing the resist on the substrate, an additional processing station; and a substrate handler for moving the substrate to the wet, and/or additional processing station and moving the substrate in a direction in and/or out of the substrate processing apparatus. The additional processing station may comprise an infiltration device comprising: a reaction chamber provided with a substrate holder to hold at least one substrate with infiltrateable material; a precursor distribution and removal system comprising one or more reaction chamber valves to provide to and remove from the reaction chamber a gaseous first and/or second precursor; and, a sequence controller operably connected to the precursor distribution and removal system and comprising a memory provided with a program to execute infiltration of the infiltrateable material on the substrate when run on the sequence controller by an infiltration cycle.

The infiltration cycle may comprise: activating the precursor distribution and removal system to provide the first precursor for a first period in the reaction chamber to infiltrate the infiltrateable material on the substrate with the reaction products of the infiltrateable material and the first precursor and activating the precursor distribution and removal system to remove a portion of the first precursor from the reaction chamber for a second period. The infiltration cycle may further comprise: activating the precursor distribution and removal system to provide the second precursor for a third period in the reaction chamber to infiltrate the infiltrateable material on the substrate with the reaction products of the infiltrateable material and/or the first and/or second precursor. In the processing apparatus the substrate with the sensitive resist as the infiltrateable material may not need to leave the processing tool to be infiltrated. The infiltration may thereby be accomplished faster and the risk of contamination will be diminished. The quality of the infiltrated material may therefore be improved.

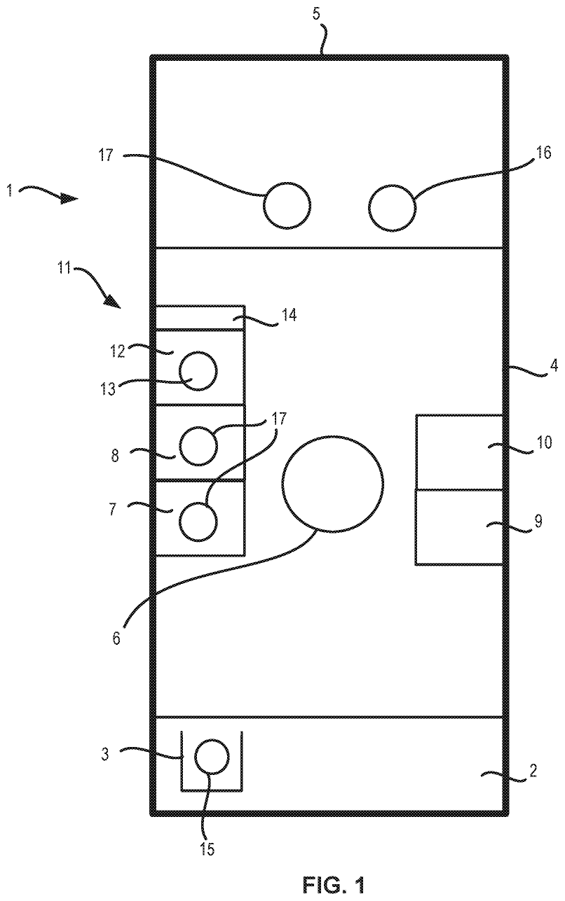

A non-limiting example of a substrate processing apparatus of the current disclosure is illustrated in FIG. 1 which comprises a schematic diagram of an exemplary substrate processing apparatus 1 according to the embodiments of the disclosure. It should be noted that the substrate processing apparatus 1 illustrated in FIG. 1 is a simplified schematic version of the exemplary substrate processing apparatus and does not contain each and every element, i.e., such as each and every valve, gas line, heating element, and reactor component, etc., that may be utilized in the fabrication of the substrate processing apparatus of the current disclosure.

The exemplary substrate processing apparatus 1 may comprise a cassette storage portion 2 on which cassettes 3 may be placed, a processing portion 4, and an interface portion 5.

The substrate processing apparatus 1 may transfer substrates to a photolithographic exposure apparatus via the interface portion 5. The interface portion 5 may be part of the substrate processing apparatus 1 or from a separate photolithographic exposure apparatus (not shown). In the processing portion 4 a substrate handler 6 for moving the substrate may be provided.

A first wet processing station 7 comprising a resist coating device for coating a resist on a substrate and a second wet processing station 8 comprising a development processing device for developing the resist on the substrate may be provided in the processing portion 4. The first and second wet processing stations 7, 8 may comprise a rotatable substrate table 17 for rotating the substrate and a liquid dispenser for providing a liquid to the surface of the substrate. Photoresist may be spun at 10 to 100 revolutions per second for 20 to 60 seconds.

The substrate handler 6 may be constructed and arranged for moving the substrate to the first, and/or second wet processing station and moving the substrate in a direction in and/or out of the substrate processing apparatus via the cassette storage portion 2 and the interface portion 5. The substrate handler 6 may have a substrate holder that is moveable in the horizontal and vertical direction for this purpose. Heating station 9 and cooling station 10 may be provided in the processing portion 4 for baking respectively cooling of the substrate and may be supplied with substrates by the substrate handler 6 as well.

The substrate processing apparatus may comprise an additional processing station 11 comprising a reaction chamber 12 provided with a substrate holder 13 to hold at least one substrate with an infiltrateable material such as a resist or hard mask. The additional processing station may comprise an infiltration device comprising a precursor distribution and removal system 14 comprising one or more reaction chamber valves to provide to and remove from the reaction chamber 12 a gaseous first and/or second precursor. The substrate handler 6 may be constructed and arranged for moving the substrate to and from the additional processing station.

In the substrate processing apparatus, a substrate 15 contained in a cassette 3 placed on the cassette storage portion 2 is loaded into the processing portion 4 and into the first wet processing station 7 by the substrate handler 6. In the first wet processing station 7 the resist coating device may coat a resist solution on the wafer W. Thereafter, the substrate may be transferred to the heating station, the additional processing station and/or the interface portion 5. At the interface portion 5 a first and second substrate table 16, 17 may be present for transfer of the substrate into the photolithographic exposure apparatus and back.

The photolithographic exposure apparatus exposes the resist on the substrate with a pattern and the substrate 15 is transferred to the second wet processing station 8 of the processing portion in the reverse path. In the second wet processing station the development processing device develops the patterned resist on the substrate 15. Thereafter, the substrate may be transferred to the heating station, the additional processing station and/or the cassette mounting portion 2 by the substrate handler 6.

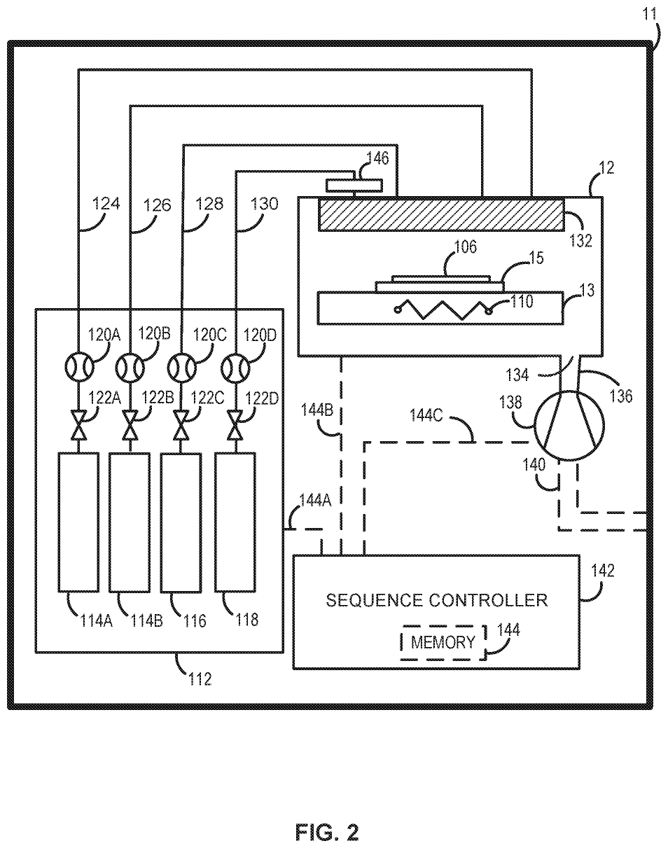

FIG. 2 illustrates a non-limiting exemplary additional processing station comprising an infiltration device for the substrate processing apparatus of FIG. 1. The additional processing station 11 may comprise a reaction chamber 12 constructed and arranged to hold at least a substrate 15 provided with an infiltrateable material 106 thereon.

Reaction chambers capable of being used to infiltrate an infiltrateable material may include reaction chambers configured for atomic layer deposition (ALD) processes, as well as reaction chambers configured for chemical vapor deposition (CVD) processes. According to some embodiments, a showerhead reaction chamber may be used. According to some embodiments, cross-flow, batch, minibatch, soaking or spatial ALD reaction chambers may be used.

In some embodiments of the disclosure, a batch reaction chamber may be used. In some embodiments, a vertical batch reaction chamber may be used. In other embodiments, a batch reaction chamber comprises a minibatch reactor configured to accommodate 10 or fewer wafers, 8 or fewer wafers, 6 or fewer wafers, 4 or fewer wafers, or 2 or fewer wafers.

Disposed within the reaction chamber 12 may be at least one substrate 15 with an infiltrateable material 106 disposed thereon, i.e., disposed on an upper surface of the substrate 15. In some embodiments of the disclosure, the substrate 15 may comprise a planar substrate or a patterned substrate. The substrate 15 may comprise one or more materials including, but not limited to, silicon (Si), germanium (Ge), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), or gallium nitride (GaN). In some embodiments of the disclosure, the substrate 104 may comprise an engineered substrate wherein a surface semiconductor layer is disposed over a bulk support with an intervening buried oxide (BOX) disposed there between.

Patterned substrates may comprise substrates that may include semiconductor device structures formed into or onto a surface of the substrate, for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), germanium tin (GeSn), or germanium (Ge). Polycrystalline or amorphous surfaces may include dielectric materials, such as oxides, oxynitrides or nitrides, such as, for example, silicon oxides and silicon nitrides.

In some embodiments of the disclosure, the substrate 15 has an infiltrateable material 106 disposed thereon, i.e., disposed on an upper surface of the substrate 15. The infiltrateable material 106 may comprise any material into which an additional species may be introduced which, when introduced into the infiltrateable material 106, may increase the etch resistance of the infiltrateable material 106. In some embodiments of the disclosure the infiltrateable material 106 may comprise at least one of a polymer resist, such as, for example, a photoresist, an extreme ultraviolet (EUV) resist, an immersion photoresist, a chemically amplified resist (CAR), or an electron beam resist (e.g., poly(methyl methacrylate) (PMMA)).

In some embodiments of the disclosure the infiltrateable material 106 may comprise a porous material, e.g., micro-porous and/or nano-porous, including porous materials such as, for example, spin-on-glasses (SOG), and spin-on-carbon (SOC). In some embodiments of the disclosure the infiltrateable material 106 may comprise one or more hardmask materials, including, but not limited to, boron carbides, amorphous carbon, silicon oxides, silicon nitrides, and silicon oxynitrides.

In some embodiments of the disclosure, the infiltrateable material 106 may comprise a patterned infiltrateable material such as a patterned resist or patterned hard mask which comprises one or more infiltrateable features. The features may be transferred during a subsequent etching process into the underlying substrate. The infiltrateable features may comprise any geometry that may be formed depending on the exposure and associated development processes and may include, but is not limited to, line features, block features, open pore features, and circular features.

In some embodiments of the disclosure, the infiltrateable material 106 may comprise a flat infiltrateable material which may be patterned during a subsequent process. For example, the infiltrateable material 106 may comprise flat resist which may be patterned during a subsequent lithographic exposure step or the infiltrateable material 106 may comprise a flat hard mask which may be patterned during a subsequent etch step.

The substrate 15 may be disposed in the reaction chamber 12 and held in position by the substrate holder 13 configured to retain at least one substrate thereon. In some embodiments of the disclosure, the infiltration processes disclosed herein may utilize processes which heat the substrate 15 and the associated infiltrateable material 106 to a suitable process temperature. Therefore, the substrate holder 13 may comprise one or more heating elements 110 which may be configured to heat the substrate 15 with the infiltrateable material 106 disposed thereon. The heating elements 110 may be configured to heat the substrate 15 to a temperature between 20 and 450° C., preferably between 50 and 150° C., more preferably between 60 and 120° C. and most preferably between 70 and 100° C., for example 85° C. In some embodiments of the disclosure, the additional station 11 is constructed and arranged to control the pressure in the reaction chamber to value between 0.001 and 1,000, preferably 0.1 to 500 and most preferably 1 to 100 Torr.

In some embodiments of the disclosure, the additional station 11 comprising an infiltration device may comprise a precursor distribution and removal system. The precursor distribution and removal system may comprise a gas delivery system 112 which may further comprise one or more precursor sources 114A and 114B constructed and arranged to provide a vapor of a number of precursors and dispense the associated vapors to the reaction chamber 12. The gas delivery system 112 may also comprise a source vessel 116 configured for storing and dispensing a purge gas that may be utilized in a purge cycle of the exemplary infiltration processes described herein. The gas delivery system 112 may also comprise a reactant source vessel 118 configured for containing and dispensing a reactant to the reaction chamber 12 to be utilized in an exemplary infiltration process described herein. As a non-limiting example, the additional station 11 may include a first precursor source 114A constructed and arranged to provide a vapor of a first precursor. In some embodiments, the first precursor source 114A may comprise a first precursor evaporator constructed and arranged to evaporate a first precursor.

In some embodiments, the first precursor source 114A may comprise a source vessel configured for storing and containing a first precursor under suitable operating conditions. For example, the first precursor may comprise a solid precursor, a liquid precursor, or a vapor phase precursor, and the source vessel may be configured for storing and containing the solid, liquid, or vapor phase precursor under suitable operating conditions. In some embodiments, the first precursor source may comprise a first precursor evaporator which may include one or more controllable heating elements which may heat the first precursor to a suitable operating temperature to thereby controllably evaporate a portion of the first precursor, the evaporated vapor subsequently being distributed to the reaction chamber 12 via suitable means to infiltrate the infiltrateable material. In some embodiments, the one or more heating elements associated with the first precursor source 114A may be configured to control the vapor pressure of the first precursor. In addition, a flow controller 120A, such as, for example a mass flow controller (MFC), may be further associated with the first precursor source 114A and may be configured to control the mass flow of the vapor produced from the first precursor source 114A, such as, for example, the first precursor evaporator. In addition to the flow controller 120A, a valve 122A, e.g., a shut-off valve, may be associated with the first precursor source 114A and may be utilized to disengage the first precursor source 114A from the reaction chamber 12, i.e., when the valve 122A is in the closed position vapor produced by the first precursor source 114A may be prevented from flowing into the reaction chamber 12.

In additional embodiments, the first precursor source 114A may further comprise a carrier gas input (not shown) such that a carrier gas (e.g., nitrogen) may be passed over or bubbled through the first precursor such that the first precursor may become entrained in the carrier gas and the carrier gas/first precursor vapor may be subsequently delivered to the reaction chamber 12 by appropriate means.

In some embodiments of the disclosure, the exemplary infiltration station 11 (FIG. 2) may comprise a precursor distribution and removal system constructed and arranged to provide the reaction chamber 12 with a vapor of the first precursor from the first precursor source 114A and to remove the vapor of the first precursor from the reaction chamber 12.

In some embodiments of the disclosure, the exemplary additional processing station 11 may comprise a precursor distribution and removal system constructed and arranged to provide the reaction chamber 12 with a vapor of the first precursor from the first precursor source 114 comprising a metal from a group comprising Aluminium (Al), Hafnium (Hf), Galium (Ga), Germanium (Ge), Zirconium (Zr), Indium (In), Lithium (Li), Tellurium (Te), Antimony (Sb), and Tin (Sn) in the reaction chamber 12.

In some embodiments of the disclosure, the exemplary additional processing station 11 may comprise a precursor distribution and removal system constructed and arranged to provide a precursor comprising a Metal Alkylamide precursor in the reaction chamber 12.

In some embodiments of the disclosure, the exemplary additional processing station 11 may comprise a precursor distribution and removal system constructed and arranged to provide a precursor selected from the group comprising trimethyl aluminum (TMA), triethylaluminum (TEA), and dimethylaluminumhydride (DMAH). The infiltration device may thereby infiltrate a metal such as an aluminium in the infiltrateable material such as for example a resist.

In some embodiments of the disclosure, the exemplary additional processing station 11 may comprise a precursor distribution and removal system constructed and arranged to provide the reaction chamber 12 with a vapor of the first precursor from the first precursor source 114 comprising a metal halide in the reaction chamber 12.

In some embodiments of the disclosure, the precursor distribution and removal system of the infiltration device is constructed and arranged to provide a precursor comprising SnI4 or SnCl4 in the reaction chamber. In some embodiments of the disclosure, the exemplary additional processing station 11 may comprise a precursor distribution and removal system constructed and arranged to provide a precursor selected from the group comprising Tetraethyltin, Tetramethyltin or Tinacetylacetonate in the reaction chamber. The infiltration device may thereby infiltrate a metal such as an aluminium in the infiltrateable material such as for example a resist.

In some embodiments of the disclosure, the exemplary additional station 11 may comprise a precursor distribution and removal system constructed and arranged to provide the reaction chamber 12 with a vapor of the first precursor from the first precursor source 114 comprising Magnesium and/or Calcium in the reaction chamber.

In some embodiments, the infiltration device may be constructed and arranged to infiltrate silicon in the infiltrateable material such as for example a resist.

In some embodiments, the first precursor source 114A may be constructed and arranged to provide a vapor of an aminosilane.

In some embodiments, the first precursor source may be constructed and arranged to provide a vapor of a 3-aminopropyl and silicon comprising compound, i.e., a silicon precursor comprising both a 3-aminopropyl component and a silicon component.

In some embodiments, the first precursor source 114A may be constructed and arranged to provide a vapor of 3-aminopropyl triethyoxysilane (APTES). For example, the first precursor source 114A may comprise a first precursor evaporator which may be constructed and arranged to evaporate 3-aminopropyl triethyoxysilane (APTES). For example, APTES may be stored and contained in a suitable source vessel and associated heating elements may be utilized to heat the APTES to a temperature of greater than 0° C., or greater than 90° C., or even greater than 230° C., in order to vaporize a portion of the APTES thereby producing a vaporized first precursor suitable for infiltrating an infiltrateable material.

In some embodiments, the first precursor source 114A may be constructed and arranged to provide a vapor of 3-aminopropyl-trimethoxysilane (APTMS). For example, the first precursor source 114A may comprise a first precursor evaporator which may be constructed and arranged to evaporate 3-aminopropyl-trimethoxysilane (APTMS). For example, APTMS may be stored and contained in a suitable source vessel and associated heating elements may be utilized to heat the APTMS to a temperature of greater than 0° C., or greater than 90° C., or even greater than 230° C., in order to vaporize a portion of the APTES thereby producing a vaporized first precursor suitable for infiltrating an infiltrateable material.

In some embodiments of the disclosure the first precursor source 114A may be constructed and arrange to provide a vapor of a silicon precursor comprising an alkoxide ligand and an additional ligand other than an alkoxide ligand. For example, the first precursor source 114A may comprise a first precursor evaporator which may be constructed and arranged to evaporate a silicon precursor comprising an alkoxide ligand and an additional ligand other than an alkoxide ligand.

In some embodiments, the first precursor source 114A may be constructed and arranged to provide a vapor of a silicon precursor comprising an amino-substituted alkyl-group attached to a silicon atom.

In more detail, the precursor distribution system may comprise gas delivery system 112, and one or more gas lines, such as, for example, gas line 124 in fluid communication with first precursor source 114A, gas line 126 in fluid communication with second precursor source 114B, gas line 128 in fluid communication with source vessel 116, and gas line 130 in fluid communication with reactant source vessel 118. As a non-limiting example, gas line 124 is fluidly connected to the first precursor source 114A and may be configured for conveying a vapor of the first precursor to the reaction chamber 12.

The precursor distribution system may further comprise a gas dispenser 132 configured for dispensing the vapor of the first precursor into reaction chamber 12 and over the substrate 104 with the infiltrateable material 106 disposed thereon, the gas dispenser 132 being in fluid communication with gas line 124, in addition to being in fluid communication with gas lines 126, 128, and 130.

As a non-limit example embodiment, the gas dispenser 132 may comprise a showerhead as illustrated in block form in FIG. 2. It should be noted that although the showerhead is illustrated in block form, the showerhead may be a relatively complex structure. In some embodiments, the showerhead may be configured to mix vapors from multiple sources prior to distributing a gas mixture to the reaction chamber 12. In alternative embodiments, the showerhead may be configured to maintain separation between multiple vapors introduced into the showerhead, the multiple vapors only coming into contact with one another in the vicinity of the substrate 15 disposed within the reaction chamber 12. Further, the showerhead may be configured to provide vertical or horizontal flow of gas into the reaction chamber 12. An exemplary gas distributor is described in U.S. Pat. No. 8,152,922, the contents of which are hereby incorporated herein by reference, to the extent such contents do not conflict with the present disclosure.

As illustrated in FIG. 2 the precursor distribution system may comprise gas delivery system 112, at least gas lines 124, 126, 128 and 130, and a gas distributor 132, however it should be noted that the precursor distribution system may include additional components not illustrated in FIG. 2, such as, for example, additional gas lines, valves, actuators, seals, and heating elements.

In addition to the precursor distribution system, the additional station 12 comprising the infiltration device may also comprise a removal system constructed and arranged to remove gasses from the reaction chamber 12. In some embodiments, the removal system may comprise an exhaust port 134 disposed within a wall of reaction chamber 12, an exhaust line 136 in fluid communication with exhaust port 134, and a vacuum pump 138 in fluid communication with the exhaust line 136 and configured for evacuating gasses from within reaction chamber 12. Once the gas or gasses have been exhausted from the reaction chamber 12 utilizing vacuum pump 138 they may be conveyed along additional exhaust line 140 and exit the additional station 11 where they may undergo further abatement processes.

To further assist in the removal of precursor gasses, i.e., reactive vapors, from within reaction chamber 12, the removal system may further comprise a source vessel 116 fluidly connected through a gas line 128 to a gas distributor 132. For example, the source vessel 116 may be configured for containing and storing a purge gas, such as, for example, argon (Ar), nitrogen (N₂), or helium (He). A flow controller 120C and valve 122C associated with the source vessel 116 may control the flow and particularly the mass flow of purge gas conveyed through gas line 128 to gas distributor 132 and into reaction chamber 12 wherein the purge gas may assist in the removal of vapor phase precursor gases, inert gasses, and byproducts from within reaction chamber 12 and particularly purge precursor gas and unreacted byproducts from an exposed surface of infiltrateable material 106. The purge gas (and any associated precursor and byproducts) may exit the reaction chamber 12 via exhaust port 134 through the utilization of vacuum pump 138.

In some embodiments of the disclosure the additional station 100 may further comprise, a sequence controller 142 operably connected to the precursor distribution system and the removal system and comprising a memory 144 provided with a program to execute infiltration of the infiltrateable material when run on the sequence controller.

In more detail, the exemplary additional station 11 may comprise a sequence controller 142 which may also comprise control lines 144A, 144B, and 144C, wherein the control lines may interface various systems and/or components of the infiltration system 100 to the sequence controller 142. For example, control line 144A may interface the sequence controller 142 with gas delivery system 112 and thereby provide control to the precursor distribution system including gas lines 124, 126, 128 and 130, as well as gas distributor 132. The control line 144B may interface the sequence controller 142 with the reaction chamber 12 thereby providing control over operation of the reaction chamber, including, but not limited to, process pressure and susceptor temperature. The control line 144C may interface the sequence controller 142 with the vacuum pump 138 such that operation and control over the gas removal system may be provided by sequence controller 142.

It should be noted that as illustrated in FIG. 2 the sequence controller 142 includes three control lines 144A, 144B, and 144C, however it should be appreciated a multitude of control lines, i.e., electrically and/or optically connected control lines, may be utilized to interface the desired systems and components comprising additional station 10 with the sequence controller 142 thereby providing overall control over the infiltration device.

In some embodiments of the disclosure, the sequence controller 142 may comprise electronic circuitry to selectively operate valves, heaters, flow controllers, manifolds, pumps and other equipment included in the exemplary infiltration device. Such circuitry and components operate to introduce precursor gasses and purge gasses from respective precursor sources 114A, 114B, reactant source vessel 118 and purge gas source vessel 116. The sequence controller 142 may also control the timing of precursor pulse sequences, temperature of the substrate and reaction chamber 12, and the pressure of the reaction chamber and various other operations necessary to provide proper operation of the additional station 11. In some embodiments, the sequence controller 142 may also comprise control software and electrically or pneumatically controlled valves to control the flow of precursors and purge gasses into and out of the reaction chamber 12. In some embodiments of the disclosure the sequence controller 142 may comprise a memory 144 provided with a program to execute infiltration of the infiltrateable material when run on the sequence controller. For example, the sequence controller 142 may include modules such as software or hardware components, such as, for example, a FPGA or ASIC, which performs certain infiltration processes. A module can be configured to reside on an addressable storage medium of the sequence controller 142 and may be configured to execute one or more infiltration processes.

In some embodiments of the disclosure, the memory 144 of sequence controller 142 may be provided with a program to execute infiltration of the infiltrateable material 106 when run on the sequence controller 142 by; activating the precursor distribution system and removal system to provide the vapor of the first precursor to the infiltrateable material 106 on the substrate 104 within the reaction chamber 12 whereby the infiltrateable material 106 on the substrate 104 within the reaction chamber 12 is infiltrated with reaction products of the reaction of the vapor of the first precursor with the infiltrateable material 106.

In some embodiments of the disclosure the exemplary additional station 10 may comprise a second precursor source 114B, such as, for example, a second precursor evaporator. In more detail, the second precursor source 114B may be constructed and arranged to provide a vapor of a second precursor. For example, the second precursor source 114B may comprise a second precursor evaporator that may be constructed and arranged to evaporate a second precursor. In some embodiments, the second precursor source 114B may be identical, or substantially identical, to the first precursor source 114A and therefore details regarding the second precursor source 114B are omitted for brevity.

In some embodiments, the precursor distribution system and removal system may be constructed and arranged to provide the reaction chamber 12 with a vapor of the second precursor from the second precursor source 114B. For example, gas line 126 may be fluidly connected to the second precursor source 114B via flow controller 120B and valve 122B, and may convey the vapor of the second precursor from the second precursor source 114B to gas distributor 132 and subsequently into the reaction chamber 12. In some embodiments, the program in the memory 144 may be programmed to execute infiltration of the infiltrateable material 106 when run on the sequence controller 142 by; activating the precursor distribution system and the removal system to provide the vapor of the second precursor to the reaction chamber 12 whereby the infiltrateable material 106 on the substrate 104 may be infiltrated with the vapor of the second precursor.

In some embodiments of the disclosure, the program in the memory 144 may be programmed to execute infiltration of the infiltrateable material 106 when run on the sequence controller 142 by; activating the precursor distribution system and removal system to provide the second precursor after the first precursor, i.e., the first precursor source 114A may provide a vapor of the first precursor into the reaction chamber 12 and infiltrate the infiltrateable material 106 with the first precursor and subsequently the second precursor source 114B may provide a vapor of the second precursor to the reaction chamber 10 and infiltrate the infiltrateable material 106 with the second precursor. The infiltration cycle of the program stored in the memory 144 may have the first period of providing the vapor of the first precursor longer than the third period of providing the vapor of the second precursor to execute infiltration of the infiltrateable material 106 when run on the sequence controller 142. Alternatively, the infiltration cycle of the program stored in the memory 144 may have the third period longer than the first period to execute infiltration of the infiltrateable material 106 when run on the sequence controller 142. The infiltration cycle of the program stored in the memory 144 may have the first period of providing the vapor of the first precursor between 0.1 to 10,000 preferably 1 to 1,000, and most preferably between 5 and 100 times longer than the third period.

In some embodiment, the sequence controller 142 may run a program on the memory 144 in order to activate the precursor distribution system and the removal system to provide the first precursor after the second precursor, i.e., the second precursor source 114B may provide a vapor of the second precursor to the reaction chamber 12 to infiltrate the infiltrateable material 106 with the second precursor vapor and subsequently the first precursor source 114A may provide a vapor of the first precursor to the reaction chamber 12 to infiltrate the infiltrateable material 106 with the first precursor vapor.

In some embodiments of the disclosure, the program stored in the memory 144 may be programmed to execute infiltration of the infiltrateable material 106 when run on the sequence controller 142 by; activating the precursor distribution system and removal system to provide the first precursor to the reaction chamber 12, followed by a purge cycle to remove excess first precursor and any byproducts from the reaction chamber, and subsequently provide the second precursor to the reaction chamber, followed by a second purge cycle to remove excess second precursor and any byproducts from the reaction chamber.

In more detail, a program mounted within the memory 144 of sequence controller 142 may first activate the first precursor source 114A and provide a vapor of the first precursor to the reaction chamber 12 to infiltrate the infiltrateable material 106 with the vapor of the first precursor, subsequently the first precursor source 114A may be deactivated and the fluid connection to the reaction chamber 12 between the first precursor source 114A and the reaction chamber 12 may disengaged, e.g., by the valve 122A associated with the first precursor source 114A. Once the first precursor source 114A is deactivated and disengaged from the reaction chamber 12 the program mounted in the memory 144 of sequence controller 142 may engage, or continue to engage, the vacuum pump 138 to exhaust excess vapor of the first precursor and any byproducts from the reaction chamber 12. In additional embodiments, in addition to utilizing the vacuum pump 138 to exhaust excess vapor of the first precursor and any byproducts from the reaction chamber 12, the program mounted in memory 144 of sequence controller 142 may activate source vessel 116 containing a source of purge gas, e.g., by opening the valve 122C associated the source vessel 116. The purge gas may flow through gas line 128 and into reaction chamber 12 via gas distributor 132 and purge the reaction chamber 12 and in particularly may purge the infiltrateable material 106 disposed upon substrate 104. The program mounted in memory 144 of sequence controller 142 may subsequently deactivate the flow of purge gas through the reaction chamber 12 and subsequently activate the second precursor source 114B to thereby provide a vapor of the second precursor to the reaction chamber 12 and particular to infiltrate the infiltrateable material 106 with the second precursor vapor provided by the second vapor source 114B. The program mounted in memory 144 of sequence controller 142 may subsequent deactivate the flow of the vapor of the second precursor to the reaction chamber 12 and subsequently activate the source vessel 116 to again purge the reaction chamber, e.g., remove excess vapor of the second precursor.

In some embodiments of the disclosure, the program mounted in the memory 144 may be programmed to execute infiltration of the infiltrateable material 106 when run on the sequence controller 142 by; activating the precursor distribution system and removal system to provide the vapor of the second precursor to the reaction chamber, followed by a purge cycle to remove excess vapor of the second precursor and any byproducts from the reaction chamber, subsequently provide the vapor of the first precursor to the reaction chamber, followed by a purge cycle to remove excess vapor of the first precursor and any byproducts from the reaction chamber.

In additional embodiments of the disclosure, the additional station 10 may comprise an infiltration device comprising a sequential infiltration synthesis (SIS) device. For example, a sequential infiltration synthesis (SIS) device may be constructed and arranged to provide alternating, self-limiting exposures of the infiltrateable material to two or more vapor phase precursors.

In additional embodiments of the disclosure, in addition to the first precursor source 114A and the second precursor source 114B, the exemplary additional station 11 may further comprise a reactant source vessel 118 and a reactant supply line, i.e., gas line 130, constructed and arranged to provide a reactant comprising an oxygen precursor to the reaction chamber 12.

In some embodiments of the disclosure, reactant source vessel 118 may comprise a reactant in the solid phase, in the liquid phase, or in the vapor phase. In some embodiments, the reactant source vessel 118 may comprise a reactant evaporator, i.e., one or more heating elements may be associated with the reactant source vessel to enable evaporation of the reactant and thereby provide a vaporized reactant comprising an oxygen precursor to the reaction chamber 12. In some embodiments, the control of the flow of the vapor reactant comprising an oxygen precursor to the reaction chamber may be achieved through the use of the valve 122D and flow controller 120D both associated with the reactant source vessel 118. In some embodiments of the disclosure wherein the reactant source vessel 118 further comprises a reactant evaporator, the reactant evaporator may be constructed and arranged to evaporate at least one of water (H₂O), or hydrogen peroxide (H₂O₂) as the reactant comprising an oxygen precursor.

In some embodiments of the disclosure, the reactant source vessel 118 may store and dispense a gaseous oxygen precursor to the reaction chamber 12 via reactant supply line 130 and gas distributor 132. In some embodiments, the gaseous oxygen precursor may comprise at least one of ozone (O₃), or molecular oxygen (O₂).

In some embodiments of the disclosure, the exemplary infiltration station 10 may optionally further comprise a plasma generator 146. The plasma generator 146 may be constructed and arranged to generate a plasma from the gaseous oxygen precursor thereby providing one or more of atomic oxygen, oxygen ions, oxygen radicals, and excited species of oxygen to the reaction chamber 12 whereby the oxygen based plasma produced by the plasma generator 146 may react with the infiltrateable material 106 disposed over substrate 104.

In some embodiments of the disclosure, the exemplary additional station 11 may be a sequential infiltration synthesis apparatus further comprising: a reactant source vessel 118 and a reactant supply line 130 constructed and arranged to provide a reactant comprising an oxygen precursor to the reaction chamber 12, wherein the program in the memory 144 of the sequence controller 142 may be programmed to execute infiltration of the infiltrateable material 106 when run on the sequence controller 142 by activating the precursor distribution system and the removal system to remove gas from the reaction chamber 12, and activating the precursor distribution system and the removal system to provide the reactant comprising an oxygen precursor to the reaction chamber 12 whereby the infiltrateable material 106 on the substrate 104 in the reaction chamber 12 is infiltrated by the reaction of the first precursor and the reactant comprising the oxygen precursor with the infiltrateable material 106. In some embodiments the program sequence of providing the first precursor, and subsequently providing the reactant may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program mounted in the memory 114 may be programmed to execute sequential infiltration synthesis of the infiltrateable material 106 when run on the sequence controller 142 by; activating the precursor distribution system and removal system to provide the oxygen precursor to the reaction chamber from reactant source vessel 118, followed by the vapor of the first precursor from the first precursor source 114A to the reaction chamber 12, to thereby infiltrate the infiltrateable material with the first precursor and oxygen atoms. In some embodiments, the program sequence of providing the oxygen precursor followed by the vapor of the first precursor may be repeated one or more times. In some embodiments, each step in the program sequence may be followed by a purge cycle to remove excess precursor and byproducts from the reaction chamber by exhausting the reaction chamber 12 utilizing the vacuum pump 138 and optionally flowing a purge gas from source vessel 116.

In some embodiments of the disclosure, the apparatus comprises a sequential infiltration synthesis apparatus and further comprises a second precursor source 114B constructed and arranged to provide a vapor of the second precursor to the reaction chamber 12. For example, the second precursor source 114B may comprise a second precursor evaporator constructed and arranged to evaporate a second precursor. In some embodiments, the precursor distribution system and the removal system may be constructed and arranged to provide the reaction chamber 12 with the vapor of the second precursor from the second precursor source 114B and the program in the memory 144 is programmed to execute infiltration of the infiltrateable material when run on the sequence controller 142 by; activating the precursor distribution system and the removal system to provide the second precursor.

In some embodiments of the disclosure, the program in the memory 144 is programmed to execute infiltration of the infiltrateable material 106 when run on the sequence controller 142 by; activating the precursor distribution system and the removal system to provide the first precursor, subsequently the reactant, subsequently the second precursor, and subsequently the reactant.

In some embodiments of the disclosure, the program in memory 144 may be programmed to execute infiltration of the infiltrateable material 106 when run on the sequence controller 142 by; activating the precursor distribution system and removal system to repeat providing the first precursor, subsequently the reactant, subsequently the second precursor, and subsequently the reactant multiple times.

In some embodiments of the disclosure, the program in memory 144 may be programmed to execute infiltration of the infiltrateable material 106 when run on the sequence controller 142 by; activating the precursor distribution system and the removal system to remove the precursors and/or reactants from the reaction chamber in between each step of providing the first precursor, subsequently the reactant, subsequently the second precursor, and subsequently the reactant.

In some embodiments of the disclosure, the program in memory 144 may be programmed to execute infiltration of the infiltrateable material 106 when run on the sequence controller 142 by; activating the precursor distribution system and the removal system to provide the first precursor, subsequently provide the second precursor, and subsequently provide the reactant. In some embodiments the program sequence of providing the first precursor, subsequently providing the second precursor, and subsequently providing the reactant may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program in memory 144 may be programmed to execute infiltration of the infiltrateable material 106 when run on the sequence controller 142 by; activating the precursor distribution system and the removal system to provide the second precursor, subsequently provide the first precursor, and subsequently provide the reactant. In some embodiments the program sequence of providing the second precursor, subsequently providing the first precursor, and subsequently providing the reactant may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program in memory 144 may be programmed to execute infiltration of the infiltrateable material 106 when run on the sequence controller 142 by; activating the precursor distribution system and the removal system to provide the first precursor, subsequently provide the reactant, and subsequently provide the second precursor. In some embodiments the program sequence of providing the first precursor, subsequently providing the reactant, and subsequently providing the second precursor may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program in memory 144 may be programmed to execute infiltration of the infiltrateable material 106 when run on the sequence controller 142 by; activating the precursor distribution system and the removal system to provide the reactant, subsequently provide the first precursor, subsequently provide the second precursor, and subsequently provide the reactant. In some embodiments the program sequence of providing the reactant, subsequently providing the first precursor, subsequently providing the second precursor, and subsequently providing the reactant may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

In some embodiments of the disclosure, the program in memory 144 may be programmed to execute infiltration of the infiltrateable material 106 when run on the sequence controller 142 by; activating the precursor distribution system and the removal system to provide the reactant, subsequently provide the first precursor, subsequently provide the reactant, and subsequently provide the second precursor. In some embodiments the program sequence of providing the reactant, subsequently providing the first precursor, subsequently providing the reactant, and subsequently providing the second precursor may be repeated one or more times. In some embodiments each step in the program sequence may be followed by a purge cycle to remove excess precursor and byproducts from the reaction chamber by exhausting the reaction chamber 12 utilizing vacuum pump 138 and optionally flowing a purge gas from source vessel 116.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A substrate processing apparatus comprising:
a wet processing station comprising a resist coating device for coating a resist on a substrate and/or a development processing device for developing the resist on the substrate;
an additional processing station; and,
a substrate handler for moving the substrate to the wet, and/or additional processing stations and moving the substrate in a direction in and/or out of the substrate processing apparatus; wherein the additional processing station comprises an infiltration device comprising:
a reaction chamber provided with a substrate holder to hold at least one substrate with infiltrateable material;
a precursor distribution and removal system comprising one or more reaction chamber valves to provide to and remove from the reaction chamber a gaseous first precursor; and,
a sequence controller operably connected to the precursor distribution and removal system and comprising a memory provided with a program to execute infiltration of the infiltrateable material on the substrate when run on the sequence controller by an infiltration cycle comprising activating the precursor distribution and removal system to provide the first precursor for a first period in the reaction chamber to infiltrate the infiltrateable material on the substrate.

2. The substrate processing apparatus according to claim 1, wherein the infiltration cycle stored in the memory further comprises activating the precursor distribution and removal system to remove a portion of the first precursor from the reaction chamber for a second period.

3. The substrate processing apparatus according to claim 2, wherein the precursor distribution and removal system comprises one or more reaction chamber valves to provide to and remove from the reaction chamber a gaseous second precursor and the infiltration cycle stored in the memory further comprises activating the precursor distribution and removal system to provide the second precursor for a third period in the reaction chamber to infiltrate the infiltrateable material on the substrate with the reaction products of the reaction of the infiltrateable material or the first precursor with the second precursor.

4. The substrate processing apparatus according to claim 3, wherein the infiltration cycle stored in the memory further comprises activating the precursor distribution and removal system to remove a portion of the second precursor from the reaction chamber for a fourth period and repeating the infiltration cycle between 1 to 60, preferably 1 to 10 and most preferably between 1 and 3 times.

5. The substrate processing apparatus according to claim 3, wherein the infiltration cycle stored in the memory has the first period longer than the third period.

6. The substrate processing apparatus according to claim 3, wherein the infiltration cycle stored in the memory has the third period longer than the first period.

7. The substrate processing apparatus according to claim 1, wherein the infiltration cycle stored in the memory further has the first period between 0.1 to 10,000 preferably 1 to 1,000, and most preferably between 5 and 100 times the third period.

8. The substrate processing apparatus according to claim 1, wherein the additional processing station is constructed and arranged to infiltrate a metal in the infiltrateable material.

9. The substrate processing apparatus according to claim 1, wherein the precursor distribution and removal system of the additional processing station is constructed and arranged to provide a metal halide in the reaction chamber.

10. The substrate processing apparatus according to claim 1, wherein the precursor distribution and removal system of the additional processing station is constructed and arranged to provide a Magnesium and/or Calcium comprising precursor in the reaction chamber.

11. The substrate processing apparatus according to claim 1, wherein the precursor distribution and removal system of the additional processing station is constructed and arranged to provide a precursor comprising a metal from a group comprising Aluminium (Al), Hafnium (Hf), Galium (Ga), Germanium (Ge), Zirconium (Zr), Indium (In), Lithium (Li), Tellurium (Te), Antimony (Sb), and Tin (Sn) in the reaction chamber.

12. The substrate processing apparatus according to claim 1, wherein the precursor distribution and removal system of the additional processing station is constructed and arranged to provide a precursor comprising SnI4 or SnCl4 in the reaction chamber.

13. The substrate processing apparatus according to claim 1, wherein the precursor distribution and removal system of the infiltration device is constructed and arranged to provide a precursor comprising a Metal Alkylamide precursor in the reaction chamber.

14. The substrate processing apparatus according to claim 1, wherein the precursor distribution and removal system of the additional processing station is constructed and arranged to provide a precursor comprising trimethyl aluminum (TMA), triethylaluminum (TEA), and dimethylaluminumhydride (DMAH), Tetraethyltin, Tetramethyltin or Tinacetylacetonate in the reaction chamber.

15. The substrate processing apparatus according to claim 1, wherein the precursor distribution and removal system of the additional processing station is constructed and arranged to provide a precursor comprising an oxidizer in the reaction chamber.

16. The substrate processing apparatus according to claim 1, wherein the additional processing station is constructed and arranged to infiltrate silicon.

17. The substrate processing apparatus according to claim 1, wherein the additional processing station is constructed and arranged to control the temperature of the reaction chamber to a value between 20 and 450° C.

18. The substrate processing apparatus according to claim 1, wherein the additional processing station is constructed and arranged to control the pressure in the reaction chamber to value between 0.001 and 1,000, preferably 0.1 to 500 and most preferably 1 to 100 Torr.

19. The substrate processing apparatus according to claim 1, wherein the wet processing station comprises:
a first wet processing station comprising a resist coating device for coating a resist on a substrate; and,
a second wet processing station comprising a development processing device for developing the resist.

20. The substrate processing apparatus according to claim 1, wherein the wet processing station comprises a rotatable substrate table for rotating the substrate and a liquid dispenser for providing a liquid to the surface of the substrate.

21. The substrate processing apparatus according to claim 1, wherein the infiltrateable material comprises a patterned resist layer and the substrate handler is constructed and arranged to move the substrate from the development processing device in the wet processing station to the additional processing station to infiltrate the patterned resist.

22. The substrate processing apparatus according to claim 1, wherein the infiltrateable material comprises a flat resist layer and the substrate handler is constructed and arranged to move the substrate from the resist coating device in the wet processing station to the additional processing station to infiltrate the resist layer.

23. A substrate processing method comprising:
providing a substrate to a substrate processing apparatus;
moving the substrate to a resist coating device in a wet processing station of the substrate processing apparatus with a substrate handler;
coating a resist layer on the substrate;
moving the coated substrate with the substrate handler to a lithographic apparatus for patterning;
receiving a substrate with a patterned resist layer by the substrate processing apparatus from the lithographic apparatus;
moving the substrate to a development processing device in the wet processing station with the substrate handler;
developing the patterned resist layer on the substrate;
moving the substrate with the patterned resist layer to a substrate table of an additional processing station with the substrate handler; and
providing a first gaseous precursor for a first period in the reaction chamber to infiltrate the patterned resist layer material on the substrate.
